(19) United States
(12) Patent Application Publication
(10) Pub. No.: US 2023/0078494 A1
(43) Pub. Date: Mar. 16, 2023

(54) Multi-Layered Composite For EMI Shielding

(71) Applicant: Ticona LLC, Florence, KY (US)

(72) Inventors: Prabuddha Bansal, Florence, KY (US); Suresh Subramonian, Cary, NC (US); SooHee Choi, Gyeonggi-do Province (KR); Young-Chul Yang, Seoul (KR)

(21) Appl. No.: 17/893,267

(22) Filed: Aug. 23, 2022

Related U.S. Application Data
(60) Provisional application No. 63/238,280, filed on Aug. 30, 2021.

(51) Int. Cl. C08K 3/04; C08K 7/14; C08K 3/34; B41M 5/00; B41M 7/00

(52) U.S. Cl. CPC C08K 3/04; C08K 7/14; C08K 3/346; B41M 5/0023; B41M 7/009; B41M 7/0081; B41M 5/0047; B41M 5/0064; B41M 5/0011

(57) ABSTRACT

A multi-layered composite comprising a substrate and a conductive film is provided. The substrate contains a polymer composition that contains a thermoplastic polymer having a deflection temperature under load of about 40° C. or more as determined in accordance with ISO 75-2:2013 at a load of 1.8 MPa. The conductive film contains a noble metal. The composite exhibits an electromagnetic interference shielding effectiveness of about 25 decibels or more as determined in accordance with ASTM D4935-18 at a frequency of 10 GHz and thickness of 3 millimeters.

### RELATED APPLICATION

The present application is based upon and claims priority to U.S. Provisional Patent Application Ser. No. 63/238,280, having a filing date of Aug. 30, 2021, which is incorporated herein by reference.

### BACKGROUND OF THE INVENTION

Electronic components (e.g., printed circuit board, antenna elements, radio frequency devices, sensors, light sensing and/or transmitting elements (e.g., fibers optics), cameras, global positioning devices, etc.) are often received within a housing structure to protect them from weather, such as sunlight, wind, and moisture. Typically, such housings are formed from materials that allow the passage of electromagnetic signals (e.g., radiofrequency signals or light). While these materials are suitable in some applications, problems can nevertheless occur at higher frequency ranges, such as those associated with LTE or 5G systems. A radar module, for instance, typically contains one or more printed circuit boards having electrical components dedicated to handling radio frequency (RF) radar signals, digital signal processing tasks, etc. To ensure that these components operate effectively at high frequencies, they are generally received in a housing structure and then covered with a radome that is transparent to radio waves. Because other surrounding electrical devices can generate electromagnetic interference (“EMI”) that can impact the accurate operation of the radar module, an aluminum plate is often positioned between the housing and printed circuit board as a separate component. Further, it is also generally necessary to employ a heat sink (e.g., thermal pad) on the circuit board to help draw heat away from the components. Unfortunately, the addition of such components can add a substantial amount of cost and weight, which is particularly disadvantageous as the automotive industry is continuing to require smaller and lighter components. As such, a need currently exists for an electronic structure (e.g., module) that does not require the need for separate component, such as an aluminum plate or heat sink.

### SUMMARY OF THE INVENTION

In accordance with one embodiment of the present invention, a multi-layered composite is disclosed that comprises a substrate defining a first surface and an opposing second surface and a conductive film disposed on the first surface that contains a noble metal. The substrate contains a polymer composition that includes a polymer matrix, wherein the polymer matrix contains a thermoplastic polymer having a deflection temperature under load of about 40° C. or more as determined in accordance with ISO 75-2:2013 at a load of 1.8 MPa. Further, the composite exhibits an electromagnetic interference shielding effectiveness of about 25 decibels or more as determined in accordance with ASTM D4935-18 at a frequency of 10 GHz and thickness of 3 millimeters.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 is an exploded perspective view of one embodiment of an electronic module that may employ the composite of the present invention;

FIG. 2 depicts one embodiment of a 5G system that may employ the composite of the present invention;

FIG. 3 depicts one embodiment of a two-layered composite formed in accordance with the present invention;

FIG. 4 depicts one embodiment of a three-layered composite formed in accordance with the present invention; and

FIG. 5 depicts one embodiment of a five-layered composite formed in accordance with the present invention.

### DETAILED DESCRIPTION

It is to be understood by one of ordinary skill in the art that the present discussion is a description of exemplary embodiments only, and is not intended as limiting the broader aspects of the present invention.

Generally speaking, the present invention is directed to a multi-layered composite for use in applications that require EMI shielding. The composite contains a substrate and a conductive film disposed on a surface thereof. Through careful selection of the particular nature of these layers, as well as the manner in which they are formed, the resulting composite can exhibit a high degree of EMI shielding effectiveness at high frequency ranges. More particularly, the EMI shielding effectiveness (“SE”) may be about 25 decibels (dB) or more, in some embodiments about 30 dB or more, in some embodiments about 35 dB or more, and in some embodiments, from about 40 dB to about 100 dB, as determined in accordance with ASTM D4935-18 at a high frequency, such as 10 GHz. Notably, it has been discovered that the EMI shielding effectiveness may remain stable over a high frequency range, including 5G frequencies, such as about 0.4 GHz or more, in some embodiments about 1 GHz or more, in some embodiments about 1.5 GHz or more, in some embodiments from about 1.5 GHz to about 20 GHz, in some embodiments from about 1.5 GHz to about 18 GHz, and in some embodiments, from about 2 GHz to about 16 GHz. The EMI shielding effectiveness may also be within the desired range for a variety of different composite thicknesses, such as from about 0.5 to about 10 millimeters, in some embodiments from about 0.8 to about 5 millimeters, and in some embodiments, from about 1 to about 4 millimeters (e.g., 1 millimeter, 1.6 millimeters, or 3 millimeters). Within these high frequency and/or thickness ranges, for example, the average EMI shielding effectiveness may be about 25 dB or more, in some embodiments about 30 dB or more, in some embodiments about 35 dB or more, and in some embodiments, from about 40 dB to about 100 dB. Likewise, the minimum EMI shielding effectiveness may be about 25 dB or more, in some embodiments about 30 dB or more, in some embodiments about 35 dB or more, and in some embodiments, from about 40 dB to about 100 dB.

Various embodiments of the present invention will now be described in more detail.

### I. Composite

A. Substrate

The substrate is generally formed from a polymer composition using a variety of different techniques. In one embodiment, for instance, the substrate may be formed using a molding technique, such as injection molding, low-pressure injection molding, extrusion compression molding, gas injection molding, foam injection molding, low-pressure gas injection molding, low-pressure foam injection molding, gas extrusion compression molding, foam extrusion compression molding, extrusion molding, foam extrusion molding, compression molding, foam compression molding, gas compression molding, etc. For example, an injection molding system may be employed that includes a mold within which the polymer composition may be injected. The time inside the injector may be controlled and optimized so that polymer matrix is not pre-solidified. When the cycle time is reached and the barrel is full for discharge, a piston may be used to inject the composition to the mold cavity. Compression molding systems may also be employed. As with injection molding, the shaping of the polymer composition into the desired article also occurs within a mold. The composition may be placed into the compression mold using any known technique, such as by being picked up by an automated robot arm. The temperature of the mold may be maintained at or above the solidification temperature of the polymer matrix for a desired time period to allow for solidification. The molded product may then be solidified by bringing it to a temperature below that of the melting temperature. The resulting product may be de-molded. The cycle time for each molding process may be adjusted to suit the polymer matrix, to achieve sufficient bonding, and to enhance overall process productivity.

The polymer composition used to form the substrate generally includes a polymer matrix and optionally one or more additional components. The nature and concentration of the polymer matrix and optional components may be selectively controlled to achieve certain desired properties for the resulting substrate. For example, the polymer composition may be thermally conductive, such as exhibiting an in-plane thermal conductivity of about 1 W/m-K or more, in some embodiments about 3 W/m-K or more, in some embodiments about 5 W/m-K or more, in some embodiments from about 7 to about 50 W/m-K, and in some embodiments, from about 10 to about 35 W/m-K, as determined in accordance with ASTM E 1461-13. The composition may also exhibit a through-plane thermal conductivity of about 0.3 W/m-K or more, in some embodiments about 0.5 W/m-K or more, in some embodiments about 0.40 W/m-K or more, in some embodiments from about 1 to about 15 W/m-K, and in some embodiments, from about 1 to about 10 W/m-K, as determined in accordance with ASTM E 1461-13. While being thermally conductive, the polymer composition may nevertheless be insulative in nature and thus exhibit a relatively high degree of electrical resistance. The surface resistivity may, for instance, be about 1×10¹⁴ ohms or more, in some embodiments about 1×10¹⁵ ohms or more, in some embodiments about 1×10¹⁶ ohms or more, and in some embodiments, about 1×10¹⁷ ohms or more, such as determined in accordance at a temperature of about 20° C. in accordance with IEC 62631-3-1:2016. The volume resistivity may likewise be about 1×10¹² ohm-m or more, in some embodiments about 1×10¹³ ohm-m or more, in some embodiments about 1×10¹⁴ ohm-m or more, and in some embodiments, about 1×10¹⁵ ohm-m or more, such as determined at a temperature of about 20° C. in accordance with IEC 62631-3-1:2016.

The polymer composition also generally has excellent mechanical properties. For example, the polymer composition may exhibit a Charpy unnotched impact strength of about 20 kJ/m² or more, in some embodiments from about 30 to about 80 kJ/m², and in some embodiments, from about 40 to about 60 kJ/m², measured at according to ISO Test No. 179-1:2010) (technically equivalent to ASTM D256-10e1) at various temperatures, such as within a temperature range of from about −50° C. to about 85° C. (e.g., 23° C.). The tensile and flexural mechanical properties may also be good. For example, the polymer composition may exhibit a tensile strength of about 50 MPa or more, in some embodiments from about 50 MPa or more 300 MPa, in some embodiments from about 80 to about 500 MPa, and in some embodiments, from about 85 to about 250 MPa; a tensile break strain of about 0.1% or more, in some embodiments from about 0.2% to about 5%, and in some embodiments, from about 0.3% to about 2.5%; and/or a tensile modulus of from about 3,500 MPa to about 30,000 MPa, in some embodiments from about 6,000 MPa to about 28,000 MPa, and in some embodiments, from about 15,000 MPa to about 25,000 MPa. The tensile properties may be determined in accordance with ISO Test No. 527-1:2019 (technically equivalent to ASTM D638-14) at various temperatures, such as within a temperature range of from about −50° C. to about 85° C. (e.g., 23° C.). The polymer composition may also exhibit a flexural strength of from about 100 to about 500 MPa, in some embodiments from about 130 to about 400 MPa, and in some embodiments, from about 140 to about 250 MPa; a flexural break strain of about 0.5% or more, in some embodiments from about 0.6% to about 5%, and in some embodiments, from about 0.7% to about 2.5%; and/or a flexural modulus of from about 5,000 MPa to about 60,000 MPa, in some embodiments from about 20,000 MPa to about 55,000 MPa, and in some embodiments, from about 30,000 MPa to about 50,000 MPa. The flexural properties may be determined in accordance with ISO Test No. 178:2019 (technically equivalent to ASTM D790-17) at various temperatures, such as within a temperature range of from about −50° C. to about 85° C. (e.g., 23° C.).

i. Polymer Matrix

As noted, the substrate generally contains a polymer composition that includes a polymer matrix. The polymer matrix contains one or more high performance, thermoplastic polymers having a high degree of heat resistance, such as reflected by a deflection temperature under load (“DTUL”) of about 40° C. or more, in some embodiments about 50° C. or more, in some embodiments about 60° C. or more, in some embodiments from about from about 80° C. to about 250° C., and in some embodiments, from about 100° C. to about 200° C., as determined in accordance with ISO 75-2:2013 at a load of 1.8 MPa. In addition to exhibiting a high degree of heat resistance, the thermoplastic polymers also typically have a high glass transition temperature, such as about 10° C. or more, in some embodiments about 20° C. or more, in some embodiments about 30° C. or more, in some embodiments about 40° C. or more, in some embodiments about 50° C. or more, and in some embodiments, from about 60° C. to about 320° C. When semi-crystalline or crystalline polymers are employed, the high performance polymers may also have a high melting temperature, such as about 140° C. or more, in some embodiments from about 150° C. to about 400° C., and in some embodiments, from about 200° C. to about 380° C. The glass transition and melting temperatures may be determined as is well known in the art using differential scanning calorimetry (“DSC”), such as determined by ISO 11357-2:2020 (glass transition) and 11357-3:2018 (melting).

Suitable high performance, thermoplastic polymers for this purpose may include, for instance, polyolefins (e.g., ethylene polymers, propylene polymers, etc.), polyamides (e.g., aliphatic, semi-aromatic, or aromatic polyamides), polyesters, polyarylene sulfides, liquid crystalline polymers (e.g., wholly aromatic polyesters, polyesteramides, etc.), polycarbonates, etc., as well as blends thereof. The exact choice of the polymer system will depend upon a variety of factors, such as the nature of other fillers included within the composition, the manner in which the composition is formed and/or processed, and the specific requirements of the intended application.

Aromatic polymers, for instance, are particularly suitable for use in the polymer matrix. The aromatic polymers can be substantially amorphous, semi-crystalline, or crystalline in nature. One example of a suitable semi-crystalline aromatic polymer, for instance, is an aromatic polyester, which may be a condensation product of at least one diol (e.g., aliphatic and/or cycloaliphatic) with at least one aromatic dicarboxylic acid, such as those having from 4 to 20 carbon atoms, and in some embodiments, from 8 to 14 carbon atoms. Suitable diols may include, for instance, neopentyl glycol, cyclohexanedimethanol, 2,2-dimethyl-1,3-propane diol and aliphatic glycols of the formula HO(CH₂)ₙOH where n is an integer of 2 to 10. Suitable aromatic dicarboxylic acids may include, for instance, isophthalic acid, terephthalic acid, 1,2-di(p-carboxyphenyl)ethane, 4,4′-dicarboxydiphenyl ether, etc., as well as combinations thereof. Fused rings can also be present such as in 1,4- or 1,5- or 2,6-naphthalene-dicarboxylic acids. Particular examples of such aromatic polyesters may include, for instance, poly(ethylene terephthalate) (PET), poly(1,4-butylene terephthalate) (PBT), poly(1,3-propylene terephthalate) (PPT), poly(1,4-butylene 2,6-naphthalate) (PBN), poly(ethylene 2,6-naphthalate) (PEN), poly(1,4-cyclohexylene dimethylene terephthalate) (PCT), as well as mixtures of the foregoing.

Derivatives and/or copolymers of aromatic polyesters (e.g., polyethylene terephthalate) may also be employed. For instance, in one embodiment, a modifying acid and/or diol may be used to form a derivative of such polymers. As used herein, the terms “modifying acid” and “modifying diol” are meant to define compounds that can form part of the acid and diol repeat units of a polyester, respectively, and which can modify a polyester to reduce its crystallinity or render the polyester amorphous. Examples of modifying acid components may include, but are not limited to, isophthalic acid, phthalic acid, 1,3-cyclohexanedicarboxylic acid, 1,4-cyclohexane dicarboxylic acid, 2,6-naphthaline dicarboxylic acid, succinic acid, glutaric acid, adipic acid, sebacic acid, suberic acid, 1,12-dodecanedioic acid, etc. In practice, it is often preferable to use a functional acid derivative thereof such as the dimethyl, diethyl, or dipropyl ester of the dicarboxylic acid. The anhydrides or acid halides of these acids also may be employed where practical. Examples of modifying diol components may include, but are not limited to, neopentyl glycol, 1,4-cyclohexanedimethanol, 1,2-propanediol, 1,3-propanediol, 2-methy-1,3-propanediol, 1,4-butanediol, 1,6-hexanediol, 1,2-cyclohexanediol, 1,4-cyclohexanediol, 1,2-cyclohexanedimethanol, 1,3-cyclohexanedimethanol, 2,2,4,4-tetramethyl 1,3-cyclobutane diol, Z,8-bis(hydroxymethyltricyclo-[5.2.1.0]-decane wherein Z represents 3, 4, or 5; 1,4-bis(2-hydroxyethoxy)benzene, 4,4′-bis(2-hydroxyethoxy) diphenylether [bis-hydroxyethyl bisphenol A], 4,4′-Bis(2-hydroxyethoxy)diphenylsulfide [bis-hydroxyethyl bisphenol S] and diols containing one or more oxygen atoms in the chain, e.g. diethylene glycol, triethylene glycol, dipropylene glycol, tripropylene glycol, etc. In general, these diols contain 2 to 18, and in some embodiments, 2 to 8 carbon atoms. Cycloaliphatic diols can be employed in their cis- or trans-configuration or as mixtures of both forms.

The aromatic polyesters, such as described above, typically have a DTUL value of from about 40° C. to about 80° C., in some embodiments from about 45° C. to about 75° C., and in some embodiments, from about 50° C. to about 70° C. as determined in accordance with ISO 75-2:2013 at a load of 1.8 MPa. The aromatic polyesters likewise typically have a glass transition temperature of from about 30° C. to about 120° C., in some embodiments from about 40° C. to about 110° C., and in some embodiments, from about 50° C. to about 100° C., such as determined by ISO 11357-2:2020, as well as a melting temperature of from about 170° C. to about 300° C., in some embodiments from about 190° C. to about 280° C., and in some embodiments, from about 210° C. to about 260° C., such as determined in accordance with ISO 11357-2:2018. The aromatic polyesters may also have an intrinsic viscosity of from about 0.1 dl/g to about 6 dl/g, in some embodiments from about 0.2 to about 5 dl/g, and in some embodiments from about 0.3 to about 1 dl/g, such as determined in accordance with ISO 1628-5:1998.

Polyarylene sulfides are also suitable semi-crystalline aromatic polymers. The polyarylene sulfide may be homopolymers or copolymers. For instance, selective combination of dihaloaromatic compounds can result in a polyarylene sulfide copolymer containing not less than two different units. For instance, when p-dichlorobenzene is used in combination with m-dichlorobenzene or 4,4′-dichlorodiphenylsulfone, a polyarylene sulfide copolymer can be formed containing segments having the structure of formula:

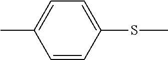

and segments having the structure of formula:

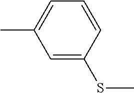

or segments having the structure of formula:

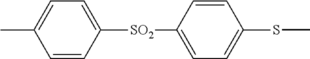

The polyarylene sulfide may be linear, semi-linear, branched or crosslinked. Linear polyarylene sulfides typically contain 80 mol % or more of the repeating unit —(Ar—S)—. Such linear polymers may also include a small amount of a branching unit or a cross-linking unit, but the amount of branching or cross-linking units is typically less than about 1 mol % of the total monomer units of the polyarylene sulfide. A linear polyarylene sulfide polymer may be a random copolymer or a block copolymer containing the above-mentioned repeating unit. Semi-linear polyarylene sulfides may likewise have a cross-linking structure or a branched structure introduced into the polymer a small amount of one or more monomers having three or more reactive functional groups. By way of example, monomer components used in forming a semi-linear polyarylene sulfide can include an amount of polyhaloaromatic compounds having two or more halogen substituents per molecule which can be utilized in preparing branched polymers. Such monomers can be represented by the formula R′Xₙ, where each X is selected from chlorine, bromine, and iodine, n is an integer of 3 to 6, and R′ is a polyvalent aromatic radical of valence n which can have up to about 4 methyl substituents, the total number of carbon atoms in R′ being within the range of 6 to about 16. Examples of some polyhaloaromatic compounds having more than two halogens substituted per molecule that can be employed in forming a semi-linear polyarylene sulfide include 1,2,3-trichlorobenzene, 1,2,4-trichlorobenzene, 1,3-dichloro-5-bromobenzene, 1,2,4-triiodobenzene, 1,2,3,5-tetrabromobenzene, hexachlorobenzene, 1,3,5-trichloro-2,4,6-trimethylbenzene, 2,2′,4,4′-tetrachlorobiphenyl, 2,2′,5,5′-tetra-iodobiphenyl, 2,2′,6,6′-tetrabromo-3,3′,5,5′-tetramethylbiphenyl, 1,2,3,4-tetrachloronaphthalene, 1,2,4-tribromo-6-methylnaphthalene, etc., and mixtures thereof.

The polyarylene sulfides, such as described above, typically have a DTUL value of from about 70° C. to about 220° C., in some embodiments from about 90° C. to about 200° C., and in some embodiments, from about 120° C. to about 180° C. as determined in accordance with ISO 75-2:2013 at a load of 1.8 MPa. The polyarylene sulfides likewise typically have a glass transition temperature of from about 50° C. to about 120° C., in some embodiments from about 60° C. to about 115° C., and in some embodiments, from about 70° C. to about 110° C., such as determined by ISO 11357-2:2020, as well as a melting temperature of from about 220° C. to about 340° C., in some embodiments from about 240° C. to about 320° C., and in some embodiments, from about 260° C. to about 300° C., such as determined in accordance with ISO 11357-3:2018.

As indicated above, substantially amorphous polymers may also be employed that lack a distinct melting point temperature. Suitable amorphous polymers may include, for instance, aromatic polycarbonates, which typically contains repeating structural carbonate units of the formula —R¹—O—C(O)—O—. The polycarbonate is aromatic in that at least a portion (e.g., 60% or more) of the total number of R¹ groups contain aromatic moieties and the balance thereof are aliphatic, alicyclic, or aromatic. In one embodiment, for instance, R¹ may a C₆₋₃₀ aromatic group, that is, contains at least one aromatic moiety. Typically, R¹ is derived from a dihydroxy aromatic compound of the general formula HO—R¹—OH, such as those having the specific formula referenced below:

HO-A¹-Y¹-A²-OH

wherein,

A¹ and A² are independently a monocyclic divalent aromatic group; and

Y¹ is a single bond or a bridging group having one or more atoms that separate A¹ from A². In one particular embodiment, the dihydroxy aromatic compound may be derived from the following formula (I):

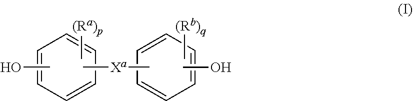

wherein,

R^{a} and R^{b} are each independently a halogen or C₁₋₁₂ alkyl group, such as a C₁₋₃ alkyl group (e.g., methyl) disposed meta to the hydroxy group on each arylene group;

p and q are each independently 0 to 4 (e.g., 1); and

X^{a} represents a bridging group connecting the two hydroxy-substituted aromatic groups, where the bridging group and the hydroxy substituent of each C₆ arylene group are disposed ortho, meta, or para (specifically para) to each other on the C₆ arylene group.

In one embodiment, X^{a} may be a substituted or unsubstituted C₃₋₁₈ cycloalkylidene, a C₁₋₂₅ alkylidene of formula —C(R^{c})(R^{d})— wherein R^{c} and R^{d} are each independently hydrogen, C₁₋₁₂ alkyl, C₁₋₁₂ cycloalkyl, C₇₋₁₂ arylalcyl, C₇₋₁₂ heteroalkyl, or cyclic C₇₋₁₂ heteroarylalkyl, or a group of the formula —C(═R^{e})— wherein R^{e} is a divalent C₁₋₁₂ hydrocarbon group. Exemplary groups of this type include methylene, cyclohexylmethylene, ethylidene, neopentylidene, and isopropylidene, as well as 2-[2.2.1]-bicycloheptylidene, cyclohexylidene, cyclopentylidene, cyclododecylidene, and adamantylidene. A specific example wherein X^{a} is a substituted cycloalkylidene is the cyclohexylidene-bridged, alkyl-substituted bisphenol of the following formula (II):

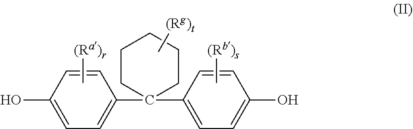

wherein,

R^{a′} and R^{b} are each independently C₁₋₁₂ alkyl (e.g., C₁₋₄ alkyl, such as methyl), and may optionally be disposed meta to the cyclohexylidene bridging group;

R^{g} is C₁₋₁₂ alkyl (e.g., C₁₋₄ alkyl) or halogen;

r and s are each independently 1 to 4 (e.g., 1); and

t is 0 to 10, such as 0 to 5.

The cyclohexylidene-bridged bisphenol can be the reaction product of two moles of o-cresol with one mole of cyclohexanone. In another embodiment, the cyclohexylidene-bridged bisphenol can be the reaction product of two moles of a cresol with one mole of a hydrogenated isophorone (e.g., 1,1,3-trimethyl-3-cyclohexane-5-one). Such cyclohexane-containing bisphenols, for example the reaction product of two moles of a phenol with one mole of a hydrogenated isophorone, are useful for making polycarbonate polymers with high glass transition temperatures and high heat distortion temperatures.

In another embodiment, X^{a} may be a C₁₋₁₈ alkylene group, a C₃₋₁₈ cycloalkylene group, a fused C₆₋₁₈ cycloalkylene group, or a group of the formula —B¹—W—B²—, wherein B¹ and B² are independently a C₁₋₆ alkylene group and W is a C₃₋₁₂ cycloalkylidene group or a C₆₋₁₆ arylene group.

X^{a} may also be a substituted C₃₋₁₈ cycloalkylidene of the following formula (III):

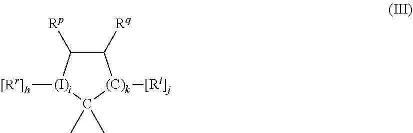

wherein,

R^{r}, R^{p}, R^{q}, and R^{t} are each independently hydrogen, halogen, oxygen, or C₁₋₁₂ organic groups;

I is a direct bond, a carbon, or a divalent oxygen, sulfur, or —N(Z)—, wherein Z is hydrogen, halogen, hydroxy, C₁₋₁₂ alkyl, C₁₋₁₂ alkoxy, or C₁₋₁₂ acyl;

h is 0 to 2;

j is 1 or 2;

i is 0 or 1; and

k is 0 to 3, with the proviso that at least two of R^{r}, R^{p}, R^{q}, and R^{t} taken together are a fused cycloaliphatic, aromatic, or heteroaromatic ring.

Other useful aromatic dihydroxy aromatic compounds include those having the following formula (IV):

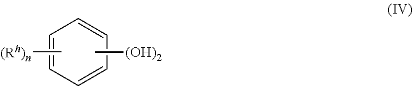

wherein,

R^{h} is independently a halogen atom (e.g., bromine), C₁₋₁₀ hydrocarbyl (e.g., C₁₋₁₀ alkyl group), a halogen-substituted C₁₋₁₀ alkyl group, a C₆₋₁₀ aryl group, or a halogen-substituted C₆₋₁₀ aryl group;

n is 0 to 4.

Specific examples of bisphenol compounds of formula (I) include, for instance, 1,1-bis(4-hydroxyphenyl) methane, 1,1-bis(4-hydroxyphenyl) ethane, 2,2-bis(4-hydroxyphenyl)propane (hereinafter “bisphenol A” or “BPA”), 2,2-bis(4-hydroxyphenyl)butane, 2,2-bis(4-hydroxyphenyl)octane, 1,1-bis(4-hydroxyphenyl)propane, 1,1-bis(4-hydroxyphenyl) n-butane, 2,2-bis(4-hydroxy-1-methylphenyl)propane, 1,1-bis(4-hydroxy-t-butylphenyl)propane, 3,3-bis(4-hydroxyphenyl)phthalimidine, 2-phenyl-3,3-bis(4-hydroxyphenyl)phthalimidine (PPPBP), and 1,1-bis(4-hydroxy-3-methylphenyl)cyclohexane (DMBPC). In one specific embodiment, the polycarbonate may be a linear homopolymer derived from bisphenol A, in which each of A¹ and A² is p-phenylene and Y¹ is isopropylidene in formula (I).

Other examples of suitable aromatic dihydroxy compounds may include, but not limited to, 4,4′-dihydroxybiphenyl, 1,6-dihydroxynaphthalene, 2,6-dihydroxynaphthalene, bis(4-hydroxyphenyl)methane, bis(4-hydroxyphenyl)diphenylmethane, bis(4-hydroxyphenyl)-1-naphthylmethane, 1,2-bis(4-hydroxyphenyl)ethane, 1,1-bis(4-hydroxyphenyl)-1-phenylethane, 2-(4-hydroxyphenyl)-2-(3-hydroxyphenyl)propane, bis(4-hydroxyphenyl)phenylmethane, 2,2-bis(4-hydroxy-3-bromophenyl)propane, 1,1-bis (hydroxyphenyl)cyclopentane, 1,1-bis(4-hydroxyphenyl)cyclohexane, 1,1-bis(4-hydroxyphenyl)isobutene, 1,1-bis(4-hydroxyphenyl)cyclododecane, trans-2,3-bis(4-hydroxyphenyl)-2-butene, 2,2-bis(4-hydroxyphenyl)adamantane, alpha, alpha′-bis(4-hydroxyphenyl)toluene, bis(4-hydroxyphenyl)acetonitrile, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-t-butyl-4-hydroxyphenyl)propane, 2,2-bis(3-cyclohexyl-4-hydroxyphenyl)propane, 2,2-bis(3-allyl-4-hydroxyphenyl)propane, 2,2-bis(3-methoxy-4-hydroxyphenyl)propane, 2,2-bis(4-hydroxyphenyl)hexafluoropropane, 1,1-dichloro-2,2-bis(4-hydroxyphenyl)ethylene, 1,1-dibromo-2,2-bis(4-hydroxyphenyl)ethylene, 1,1-dichloro-2,2-bis(5-phenoxy-4-hydroxyphenyl)ethylene 4,4′-dihydroxybenzophenone, 3,3-bis(4-hydroxyphenyl)-2-butanone, 1,6-bis(4-hydroxyphenyl)-1,6-hexanedione, ethylene glycol bis(4-hydroxyphenyl)ether, bis(4-hydroxyphenyl)ether, bis(4-hydroxyphenyl)sulfide, bis(4-hydroxyphenyl)sulfoxide, bis(4-hydroxyphenyl)sulfone, 9,9-bis(4-hydroxyphenyl)fluorine, 2,7-dihydroxypyrene, 6,6′-dihydroxy-3,3,3′,3′-tetramethylspiro(bis)indane (“spirobiindane bisphenol”), 3,3-bis(4-hydroxyphenyl)phthalimide, 2,6-dihydroxydibenzo-p-dioxin, 2,6-dihydroxythianthrene, 2,7-dihydroxyphenoxathin, 2,7-dihydroxy-9,10-dimethylphenazine, 3,6-dihydroxydibenzofuran, 3,6-dihydroxydibenzothiophene, and 2,7-dihydroxycarbazole, resorcinol, substituted resorcinol compounds such as 5-methyl resorcinol, 5-ethyl resorcinol, 5-propyl resorcinol, 5-butyl resorcinol, 5-t-butyl resorcinol, 5-phenyl resorcinol, 5-cumyl resorcinol, 2,4,5,6-tetrafluoro resorcinol, 2,4,5,6-tetrabromo resorcinol, or the like; catechol; hydroquinone; substituted hydroquinones such as 2-methyl hydroquinone, 2-ethyl hydroquinone, 2-propyl hydroquinone, 2-butyl hydroquinone, 2-t-butyl hydroquinone, 2-phenyl hydroquinone, 2-cumyl hydroquinone, 2,3,5,6-tetramethyl hydroquinone, 2,3,5,6-tetra-t-butyl hydroquinone, 2,3,5,6-tetrafluoro hydroquinone, 2,3,5,6-tetrabromo hydroquinone, etc., as well as combinations thereof.

Aromatic polycarbonates, such as described above, typically have a DTUL value of from about 80° C. to about 300° C., in some embodiments from about 100° C. to about 250° C., and in some embodiments, from about 140° C. to about 220° C., as determined in accordance with ISO 75-2:2013 at a load of 1.8 MPa. The glass transition temperature may also be from about 50° C. to about 250° C., in some embodiments from about 90° C. to about 220° C., and in some embodiments, from about 100° C. to about 200° C., such as determined by ISO 11357-2:2020. Such polycarbonates may also have an intrinsic viscosity of from about 0.1 dl/g to about 6 dl/g, in some embodiments from about 0.2 to about 5 dl/g, and in some embodiments from about 0.3 to about 1 dl/g, such as determined in accordance with ISO 1628-4:1998.

In addition to the polymers referenced above, highly crystalline aromatic polymers may also be employed in the polymer composition. Particularly suitable examples of such polymers are liquid crystalline polymers, which have a high degree of crystallinity that enables them to effectively fill the small spaces of a mold. Liquid crystalline polymers are generally classified as “thermotropic” to the extent that they can possess a rod-like structure and exhibit a crystalline behavior in their molten state (e.g., thermotropic nematic state). Such polymer typically have a DTUL value of from about 120° C. to about 340° C., in some embodiments from about 140° C. to about 320° C., and in some embodiments, from about 150° C. to about 300° C., as determined in accordance with ISO 75-2:2013 at a load of 1.8 MPa. The polymers also have a relatively high melting temperature, such as from about 250° C. to about 400° C., in some embodiments from about 280° C. to about 390° C., and in some embodiments, from about 300° C. to about 380° C. Such polymers may be formed from one or more types of repeating units as is known in the art.

A liquid crystalline polymer may, for example, contain one or more aromatic ester repeating units, typically in an amount of from about 60 mol. % to about 99.9 mol. %, in some embodiments from about 70 mol. % to about 99.5 mol. %, and in some embodiments, from about 80 mol. % to about 99 mol. % of the polymer. The aromatic ester repeating units may be generally represented by the following Formula (V):

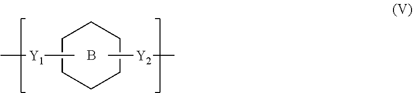

wherein,

ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and

Y₁ and Y₂ are independently O, C(O), NH, C(O)HN, or NHC(O).

Typically, at least one of Y₁ and Y₂ are C(O). Examples of such aromatic ester repeating units may include, for instance, aromatic dicarboxylic repeating units (Y₁ and Y₂ in Formula V are C(O)), aromatic hydroxycarboxylic repeating units (Y₁ is O and Y₂ is C(O) in Formula V), as well as various combinations thereof.

Aromatic dicarboxylic repeating units, for instance, may be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, terephthalic acid (“TA”), isophthalic acid (“IA”), and 2,6-naphthalenedicarboxylic acid (“NDA”). When employed, repeating units derived from aromatic dicarboxylic acids (e.g., IA, TA, and/or NDA) typically constitute from about 5 mol. % to about 60 mol. %, in some embodiments from about 10 mol. % to about 55 mol. %, and in some embodiments, from about 15 mol. % to about 50% of the polymer.

Aromatic hydroxycarboxylic repeating units may also be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. Particularly suitable aromatic hydroxycarboxylic acids are 4-hydroxybenzoic acid (“HBA”) and 6-hydroxy-2-naphthoic acid (“HNA”). When employed, repeating units derived from hydroxycarboxylic acids (e.g., HBA and/or HNA) typically constitute from about 10 mol. % to about 85 mol. %, in some embodiments from about 20 mol. % to about 80 mol. %, and in some embodiments, from about 25 mol. % to about 75% of the polymer.

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). When employed, repeating units derived from aromatic diols (e.g., HQ and/or BP) typically constitute from about 1 mol. % to about 30 mol. %, in some embodiments from about 2 mol. % to about 25 mol. %, and in some embodiments, from about 5 mol. % to about 20% of the polymer. Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). When employed, repeating units derived from aromatic amides (e.g., APAP) and/or aromatic amines (e.g., AP) typically constitute from about 0.1 mol. % to about 20 mol. %, in some embodiments from about 0.5 mol. % to about 15 mol. %, and in some embodiments, from about 1 mol. % to about 10% of the polymer. It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids, diols, amides, amines, etc. Of course, in other embodiments, the polymer may be “wholly aromatic” in that it lacks repeating units derived from non-aromatic (e.g., aliphatic or cycloaliphatic) monomers.

In one particular embodiment, the liquid crystalline polymer may be formed from repeating units derived from 4-hydroxybenzoic acid (“HBA”) and terephthalic acid (“TA”) and/or isophthalic acid (“IA”), as well as various other optional constituents. The repeating units derived from 4-hydroxybenzoic acid (“HBA”) may constitute from about 10 mol. % to about 80 mol. %, in some embodiments from about 30 mol. % to about 75 mol. %, and in some embodiments, from about 45 mol. % to about 70% of the polymer. The repeating units derived from terephthalic acid (“TA”) and/or isophthalic acid (“IA”) may likewise constitute from about 5 mol. % to about 40 mol. %, in some embodiments from about 10 mol. % to about 35 mol. %, and in some embodiments, from about 15 mol. % to about 35% of the polymer. Repeating units may also be employed that are derived from 4,4′-biphenol (“BP”) and/or hydroquinone (“HQ”) in an amount from about 1 mol. % to about 30 mol. %, in some embodiments from about 2 mol. % to about 25 mol. %, and in some embodiments, from about 5 mol. % to about 20% of the polymer. Other possible repeating units may include those derived from 6-hydroxy-2-naphthoic acid (“HNA”), 2,6-naphthalenedicarboxylic acid (“NDA”), and/or acetaminophen (“APAP”). In certain embodiments, for example, repeating units derived from HNA, NDA, and/or APAP may each constitute from about 1 mol. % to about 35 mol. %, in some embodiments from about 2 mol. % to about 30 mol. %, and in some embodiments, from about 3 mol. % to about 25 mol. % when employed.

Of course, besides aromatic polymers, aliphatic polymers may also be suitable for use as high performance, thermoplastic polymers in the polymer matrix. In one embodiment, for instance, polyamides may be employed that generally have a CO—NH linkage in the main chain and are obtained by condensation of an aliphatic diamine and an aliphatic dicarboxylic acid, by ring opening polymerization of lactam, or self-condensation of an amino carboxylic acid. For example, the polyamide may contain aliphatic repeating units derived from an aliphatic diamine, which typically has from 4 to 14 carbon atoms. Examples of such diamines include linear aliphatic alkylenediamines, such as 1,4-tetramethylenediamine, 1,6-hexanediamine, 1,7-heptanediamine, 1,8-octanediamine, 1,9-nonanediamine, 1,10-decanediamine, 1,11-undecanediamine, 1,12-dodecanediamine, etc.; branched aliphatic alkylenediamines, such as 2-methyl-1,5-pentanediamine, 3-methyl-1,5 pentanediamine, 2,2,4-trimethyl-1,6-hexanediamine, 2,4,4-trimethyl-1,6-hexanediamine, 2,4-dimethyl-1,6-hexanediamine, 2-methyl-1,8-octanediamine, 5-methyl-1,9-nonanediamine, etc.;

as well as combinations thereof. Aliphatic dicarboxylic acids may include, for instance, adipic acid, sebacic acid, etc. Particular examples of such aliphatic polyamides include, for instance, nylon-4 (poly-α-pyrrolidone), nylon-6 (polycaproamide), nylon-11 (polyundecanamide), nylon-12 (polydodecanamide), nylon-46 (polytetramethylene adipamide), nylon-66 (polyhexamethylene adipamide), nylon-610, and nylon-612. Nylon-6 and nylon-66 are particularly suitable.

It should be understood that it is also possible to include aromatic monomer units in the polyamide such that it is considered aromatic (contains only aromatic monomer units are both aliphatic and aromatic monomer units). Examples of aromatic dicarboxylic acids may include, for instance, terephthalic acid, isophthalic acid, 2,6-naphthalenedicarboxylic acid, 2,7-naphthalenedicarboxylic acid, 1,4-naphthalenedicarboxylic acid, 1,4-phenylenedioxy-diacetic acid, 1,3-phenylenedioxy-diacetic acid, diphenic acid, 4,4′-oxydibenzoic acid, diphenylmethane-4,4′-dicarboxylic acid, diphenylsulfone-4,4′-dicarboxylic acid, 4,4′-biphenyldicarboxylic acid, etc. Particularly suitable aromatic polyamides may include poly(nonarethylene terephthalamide) (PA9T), poly(nonamethylene terephthalamide/nonamethylene decanediamide) (PA9T/910), poly(nonamethylene terephthalamide/nonamethylene dodecanediamide) (PA9T/912), poly(nonamethylene terephthalamide/11-aminoundecanamide) (PA9T/11), poly(nonamethylene terephthalamide/12-aminododecanamide) (PA9T/12), poly(decamethylene terephthalamide/11-aminoundecanamide) (PA10T/11), poly(decamethylene terephthalamide/12-aminododecanamide) (PA10T/12), poly(decamethylene terephthalamide/decamethylene decanediamide) (PA10T/1010), poly(decamethylene terephthalamide/decamethylene dodecanediamide) (PA10T/1012), poly(decamethylene terephlhalamide/tetramethylene hexanediamide) (PA10T/46), poly(decamethylene terephthalamide/caprolactam) (PA10T/6), poly(decamethylene terephthalamide/hexamethylene hexanediamide) (PA10T/66), poly(dodecamethylene lerephthalamide/dodecamelhylene dodecanediarnide) (PA12T/1212), poly(dodecamethylene terephthalamide/caprolactam) (PA12T/6), poly(dodecamethylene terephthalamide/hexamethylene hexanediamide) (PA12T/66), and so forth.

The polyamide employed in the polyamide composition is typically crystalline or semi-crystalline in nature and thus has a measurable melting temperature. The melting temperature may be relatively high such that the composition can provide a substantial degree of heat resistance to a resulting part. For example, the polyamide may have a melting temperature of about 220° C. or more, in some embodiments from about 240° C. to about 325° C., and in some embodiments, from about 250° C. to about 335° C. The polyamide may also have a relatively high glass transition temperature, such as about 30° C. or more, in some embodiments about 40° C. or more, and in some embodiments, from about 45° C. to about 140° C. The glass transition and melting temperatures may be determined as is well known in the art using differential scanning calorimetry (“DSC”), such as determined by ISO Test No. 11357-2:2020 (glass transition) and 11357-3:2018 (melting).

Propylene polymers may also be suitable aliphatic high performance polymers for use in the polymer matrix. Any of a variety of propylene polymers or combinations of propylene polymers may generally be employed in the polymer matrix, such as propylene homopolymers (e.g., syndiotactic, atactic, isotactic, etc.), propylene copolymers, and so forth. In one embodiment, for instance, a propylene polymer may be employed that is an isotactic or syndiotactic homopolymer. The term “syndiotactic” generally refers to a tacticity in which a substantial portion, if not all, of the methyl groups alternate on opposite sides along the polymer chain. On the other hand, the term “isotactic” generally refers to a tacticity in which a substantial portion, if not all, of the methyl groups are on the same side along the polymer chain. In yet other embodiments, a copolymer of propylene with an α-olefin monomer may be employed. Specific examples of suitable α-olefin monomers may include ethylene, 1-butene; 3-methyl-1-butene; 3,3-dimethyl-1-butene; 1-pentene; 1-pentene with one or more methyl, ethyl or propyl substituents; 1-hexene with one or more methyl, ethyl or propyl substituents; 1-heptene with one or more methyl, ethyl or propyl substituents; 1-octene with one or more methyl, ethyl or propyl substituents; 1-nonene with one or more methyl, ethyl or propyl substituents; ethyl, methyl or dimethyl-substituted 1-decene; 1-dodecene; and styrene. The propylene content of such copolymers may be from about 60 mol. % to about 99 mol. %, in some embodiments from about 80 mol. % to about 98.5 mol. %, and in some embodiments, from about 87 mol. % to about 97.5 mol. %. The α-olefin content may likewise range from about 1 mol. % to about 40 mol. %, in some embodiments from about 1.5 mol. % to about 15 mol. %, and in some embodiments, from about 2.5 mol. % to about 13 mol. %.

Suitable propylene polymers are typically those having a DTUL value of from about 80° C. to about 250° C., in some embodiments from about 100° C. to about 220° C., and in some embodiments, from about 110° C. to about 200° C., as determined in accordance with ISO 75-2:2013 at a load of 1.8 MPa. The glass transition temperature of such polymers may likewise be from about 10° C. to about 80° C., in some embodiments from about 15° C. to about 70° C., and in some embodiments, from about 20° C. to about 60° C., such as determined by ISO 11357-2:2020. Further, the melting temperature of such polymers may be from about 50° C. to about 250° C., in some embodiments from about 90° C. to about 220° C., and in some embodiments, from about 100° C. to about 200° C., such as determined by ISO 11357-3:2018.

ii. Optional Components

If desired, the polymer matrix may constitute the entire substrate. In other embodiments, however, one or more optional components can also be incorporated into the polymer composition to achieve certain properties, such as mineral fillers, electrically conductive fillers, plating additives, reinforcing fibers (e.g., glass fibers), impact modifiers, lubricants, pigments (e.g., carbon black), antioxidants, stabilizers, surfactants, waxes, flame retardants, anti-drip additives, nucleating agents (e.g., boron nitride), and other materials added to enhance properties and processability.

In one embodiment, for example, the polymer composition may contain a mineral filler. The nature of the mineral filler may vary, such as mineral particles, mineral fibers (or “whiskers”), etc., as well as blends thereof. Suitable mineral fibers may, for instance, include those that are derived from silicates, such as neosilicates, sorosilicates, inosilicates (e.g., calcium inosilicates, such as wollastonite; calcium magnesium inosilicates, such as tremolite; calcium magnesium iron inosilicates, such as actinolite; magnesium iron inosilicates, such as anthophyllite; etc.), phyllosilicates (e.g., aluminum phyllosilicates, such as palygorskite), tectosilicates, etc.; sulfates, such as calcium sulfates (e.g., dehydrated or anhydrous gypsum); mineral wools (e.g., rock or slag wool); and so forth. Particularly suitable are inosilicates (e.g., calcium inosilicate or CaSiO₃), such as wollastonite fibers available from Nyco Minerals under the trade designation NYGLOS® (e.g., NYGLOS® 4 W or NYGLOS® 8). Such wollastonite fibers may, for instance, contain approximately 50% CaO, approximately 50% SiO₂, and various other trace components, such as Fe₂O₃, Al₂O₃, MnO, MgO, TiO2, and K₂O. As noted, the mineral fibers generally have a small size, such as a median diameter of about 25 micrometers or less, in some embodiments from about 0.1 to about 15 micrometers, in some embodiments from about 0.5 to about 14 micrometers, and in some embodiments, from about 1 to about 13 micrometers, such as determined by a laser diffraction analyzer (e.g., Microtrac S3500). The mineral fibers may also have a narrow size distribution. That is, at least about 60% by volume of the fibers, in some embodiments at least about 70% by volume of the fibers, and in some embodiments, at least about 80% by volume of the fibers may have a size within the ranges noted above. In addition to possessing a small median diameter as noted above, the mineral fibers may also have a relatively high aspect ratio (median length divided by median diameter) to help further improve the properties of the resulting polymer composition. For example, the mineral fibers may have an aspect ratio of from about 1.1 to about 100, in some embodiments from about 2 to about 50, in some embodiments from about 4 to about 30, and in some embodiments, from about 8 to about 20. The median length of such mineral fibers may, for example, range from about 1 to about 300 micrometers, in some embodiments from about 5 to about 250 micrometers, in some embodiments from about 40 to about 220 micrometers, and in some embodiments, from about 60 to about 200 micrometers, such as determined by a laser diffraction analyzer (e.g., Microtrac S3500).

Other suitable mineral fillers are mineral particles. The mineral particles may have a median diameter of about 25 micrometers or less, in some embodiments from about 0.1 to about 15 micrometers, in some embodiments from about 0.5 to about 14 micrometers, and in some embodiments, from about 1 to about 13 micrometers, such as determined by a laser diffraction analyzer (e.g., Microtrac S3500). The shape of the particles may vary as desired, such as granular, flake-shaped, etc. Flake-shaped particles, for instance, may be employed that have a relatively high aspect ratio (e.g., average diameter divided by average thickness), such as about 4 or more, in some embodiments about 8 or more, and in some embodiments, from about 10 to about 500. The average thickness of such flake-shaped particles may likewise be about 2 micrometers or less, in some embodiments from about 5 nanometers to about 1 micrometer, and in some embodiments, from about 20 nanometers to about 500 nanometers. Regardless of their shape and size, the particles are typically formed from a natural and/or synthetic silica or silicate mineral, such as talc, mica, halloysite, kaolinite, illite, montmorillonite, vermiculite, palygorskite, pyrophyllite, calcium silicate, aluminum silicate, wollastonite, silica, etc. Talc, mica, and silica are particularly suitable. Any form of mica may generally be employed, including, for instance, muscovite (KAl₂(AlSi₃)O₁₀(OH)₂), biotite (K(Mg,Fe)₃(AlSi₃)O₁₀(OH)₂), phlogopite (KMg₃(AlSi₃)O₁₀(OH)₂), lepidolite (K(Li,Al)₂₋₃(AlSi₃)O₁₀(OH)₂), glauconite (K,Na)(Al,Mg,Fe)₂(Si,Al)₄O₁₀(OH)₂), etc. Muscovite-based mica is particularly suitable for use in the polymer composition.

When employed, the mineral filler may provide a variety of benefits to the polymer composition. In one embodiment, for example, the mineral filler may be employed in an amount sufficient to increase thermal conductivity so that the composition is capable of creating a thermal pathway for heat transfer away from the resulting electronic device so that “hot spots” can be quickly eliminated and the overall temperature can be lowered during use. For example, the mineral filler may be employed in an amount of from about 10 to about 80 parts, in some embodiments from about 20 to about 70 parts, and in some embodiments, from about 30 to about 60 parts per 100 parts by weight of the polymer matrix. The mineral filler may, for instance, constitute from about 5 wt. % to about 70 wt. %, in some embodiments from about 10 wt. % to about 60 wt. %, in some embodiments from about 10 wt. % to about 55 wt. %, and in some embodiments, from about 25 wt. % to about 40 wt. % of the polymer composition. In such embodiments, the high degree of thermal conductivity can be achieved without use of conventional materials having a high degree of intrinsic thermal conductivity, which are expensive and can adversely impact other properties. For example, the polymer composition may be generally free of thermally conductive fillers having an intrinsic thermal conductivity of 50 W/m-K or more, in some embodiments 100 W/m-K or more, and in some embodiments, 150 W/m-K or more. Examples of such high intrinsic thermally conductive materials may include, for instance, boron nitride, aluminum nitride, magnesium silicon nitride, graphite (e.g., expanded graphite), silicon carbide, carbon nanotubes, zinc oxide, magnesium oxide, beryllium oxide, zirconium oxide, yttrium oxide, aluminum powder, and copper powder. While it is normally desired to minimize the presence of such high intrinsic thermally conductive materials, they may nevertheless be present if desired, such as in an amount of about 5 wt. % or less, in some embodiments about 2 wt. % or less, in some embodiments about 1 wt. % or less, in some embodiments about 0.5 wt. % or less, and in some embodiments, from about 0.001 wt. % to about 0.2 wt. % of the polymer composition.

Electrically conductive fillers may also be employed in the polymer composition, such as those having an intrinsic volume resistivity of less than about 1 ohm-cm, in some embodiments about less than about 0.1 ohm-cm, and in some embodiments, from about 1×10⁻⁸ to about 1×10⁻² ohm-cm, such as determined at a temperature of about 20° C. Examples of such electrically conductive fillers may include, for instance, electrically conductive carbon materials such as, graphite, electrically conductive carbon black, carbon fibers, graphene, carbon nanotubes, etc.; metals (e.g., metal particles, metal flakes, metal fibers, etc.); ionic liquids; and so forth. In certain embodiments, as noted above, the polymer composition is insulative in nature and thus has a high degree of electrical resistance. In such embodiments, it may be desired that the composition is generally free of electrically conductive fillers as described above, such as containing no more than about 5 wt. %, in some embodiments no more than about 2 wt. %, in some embodiments no more than about 1 wt. %, in some embodiments no more than about 0.5 wt. %, and in some embodiments, from 0 wt. % to about 0.2 wt. % of such electrically conductive fillers.

In certain embodiments, reinforcing fibers may employed to help improve the mechanical properties of the polymer composition. Examples of such reinforcing fibers includes those formed from materials that are insulative in nature, such as glass, ceramics (e.g., alumina or silica), aramids (e.g., Kevlar®), polyolefins, polyesters, etc., as well as mixtures thereof. Glass fibers are particularly suitable, such as E-glass, A-glass, C-glass, D-glass, AR-glass, R-glass, S1-glass, S2-glass, etc., and mixtures thereof. The reinforcing fibers may be in the form of randomly distributed fibers, such as when such fibers are melt blended with the high performance polymer(s) during the formation of the polymer matrix. Alternatively, the reinforcing fibers may be in the form of long fibers and impregnated with the polymer matrix in a manner such as described above. Regardless, the volume average length of the reinforcing fibers may be from about 1 to about 400 micrometers, in some embodiments from about 50 to about 400 micrometers, in some embodiments from about 80 to about 250 micrometers, in some embodiments from about 100 to about 200 micrometers, and in some embodiments, from about 110 to about 180 micrometers. The fibers may also have an average diameter of about 10 to about 35 micrometers, and in some embodiments, from about 15 to about 30 micrometers. While reinforcing fibers may be employed, the polymer composition may also be capable of achieving a high degree of mechanical strength without the need such fibers. In this regard, the polymer composition may be generally free of reinforcing fibers, such as no more than about 20 wt. %, in some embodiments no more than about 10 wt. %, and in some embodiments, from about 0 wt. % to about 5 wt. % of reinforcing fibers.

Based on the manner in which the conductive film is applied to the substrate, it is generally not necessary for the polymer composition to include plating additives, such as laser direct structuring additives (e.g., copper chromite (CuCr₂O₄)). Therefore, the resulting polymer composition may be generally free of chromium and/or copper. For example, chromium may be present in the composition in an amount of about 2,000 parts per million (“ppm”) or less, in some embodiments from about 1,500 ppm or less, in some embodiments about 1,000 ppm or less, and in some embodiments, from about 0.001 to about 500 ppm, while copper is generally present in the composition in an amount of about 1,000 ppm or less, in some embodiments from about 750 ppm or less, in some embodiments about 500 ppm or less, and in some embodiments, from about 0.001 to about 100 ppm. The content of copper and chromium may be determined using known techniques, such as by X-ray fluoroscopy (e.g., Innov-X Systems Model a-2000 X-ray fluorescence spectrometer with a Si-PiN diode detector). Of course, apart from copper chromite, the polymer composition may also be generally free of other types of conventional laser activatable additives, such as spinel crystals having the formula, AB₂O₄, wherein A is a metal cation having a valance of 2 (e.g., cadmium, chromium, manganese, nickel, zinc, copper, cobalt, iron, magnesium, tin, or titanium) and B is a metal cation having a valance of 3 (e.g., chromium, iron, aluminum, nickel, manganese, or tin) (e.g., MgAl₂O₄, ZnAl₂O₄, FeAl₂O₄, CuFe₂O₄, MnFe₂O₄, NiFe₂O₄, TiFe₂O₄, FeCr₂O₄, or MgCr₂O₄). The polymer composition may be free of such spinel crystals (i.e., 0 wt. %), or such crystals may be present in only a small concentration, such as in an amount of about 1 wt. % or less, in some embodiments about 0.5 wt. % or less, and in some embodiments, from about 0.001 wt. % to about 0.2 wt. %.

Regardless of the particular types of components employed, they may generally be melt processed or blended together with the polymer matrix in a variety of ways. For example, the components may be supplied separately or in combination to an extruder that includes at least one screw rotatably mounted and received within a barrel (e.g., cylindrical barrel) and may define a feed section and a melting section located downstream from the feed section along the length of the screw. The extruder may be a single screw or twin screw extruder. The speed of the screw may be selected to achieve the desired residence time, shear rate, melt processing temperature, etc. For example, the screw speed may range from about 50 to about 800 revolutions per minute (“rpm”), in some embodiments from about 70 to about 150 rpm, and in some embodiments, from about 80 to about 120 rpm. The apparent shear rate during melt blending may also range from about 100 seconds⁻¹ to about 10,000 seconds⁻¹, in some embodiments from about 500 seconds⁻¹ to about 5000 seconds⁻¹, and in some embodiments, from about 800 seconds⁻¹ to about 1200 seconds⁻¹. The apparent shear rate is equal to 4Q/πR³, where Q is the volumetric flow rate (“m³/s”) of the polymer melt and R is the radius (“m”) of the capillary (e.g., extruder die) through which the melted polymer flows. The resulting polymer composition can possess excellent thermal properties. For example, the melt viscosity of the polymer composition may be low enough so that it can readily flow into the cavity of a mold having small dimensions. In one particular embodiment, the polymer composition may have a melt viscosity of from about 10 to about 250 Pa-s, in some embodiments from about 15 to about 200 Pa-s, in some embodiments from about 20 to about 150 Pa-s, and in some embodiments, from about 30 to about 100 Pa-s, determined at a shear rate of 1,000 seconds⁻¹. Melt viscosity may be determined in accordance with ISO Test No. 11443:2014 at a temperature that is 15° C. higher than the melting temperature of the composition (e.g., about 340° C. for a melting temperature of about 325° C.).

B. Conductive Film

The multi-layered composite also contains a conductive film that is disposed on at least one surface of the substrate. The conductive film contains a noble metal, such as ruthenium, rhodium, palladium, osmium, platinum, gold, silver, copper, or a combination thereof. Silver is particularly suitable. The conductive film may have a relatively high specific conductance and conductive efficiency. For example, the specific conductance may be about 1×10⁵ S/m or more, in some embodiments about 1×10⁶ S/m or more, and in some embodiments, from about 1×10⁷ to about 8×10⁷ S/m at a temperature of 20° C. The conductive efficiency may likewise be about 30% or more, in some embodiments about 40% or more, and in some embodiments, about 50% or more.

The conductive film may be formed by a process that includes applying an ink that contains a noble metal or noble metal precursor to the surface of the substrate to form one or more precursor layer(s). The precursor layer(s) may thereafter be treated in a manner that forms a conductive film. When the ink contains metal particles, it is generally desired that the average size of the metal particles is relatively small, such as from about 10 nanometers to about 2 micrometers, in some embodiments from about 20 nanometers to about 1 micrometers, and in embodiments, from about 50 nanometers to about 250 micrometers. Due to in part to the relatively small size of the particles, the ink may have a relatively low viscosity, allowing it to be readily handled and applied to the substrate. The viscosity may, for instance, range from about 5 to about 250 Pascal-seconds (Pa-s), in some embodiments from about 20 Pa-s to about 200 Pa-s, and in some embodiments, from about 30 Pa-s to about 150 Pa-s, as measured with a Brookfield DV-1 viscometer (cone and plate) operating at a speed of 5 or 0.5 rpm and a temperature of 25° C. If desired, binders, thickeners, or other viscosity modifiers may be employed in the paste to increase or decrease viscosity and aid in the adherence of the film to the substrate.

Besides employing metal particles, it is also possible to employ a metal precursor in the ink that is capable of converting to a metal through treatment of the precursor layer applied to the substrate. Through such a process, the resulting conductive film may be generally free of large metal particles, which might otherwise impede the ability of the ink to coat the substrate and a lower specific conductance. For example, in such embodiments, the conductive film may be generally free of metal particles having an average diameter of about 2 micrometers or more, in some embodiments about 1 micrometer or more, in some embodiments, about 250 nanometers or more, in some embodiments about 50 nanometers or more, and in some embodiments, about 10 nanometers or more. Namely, such particles may constitute about 1 wt. % or less, in some embodiments about 0.5 wt. % or less, and in some embodiments, from 0 wt. % to about 0.2 wt. % of the conductive film. The metal precursor is capable of decomposing under the influence of heat to form a thin conductive metal film. In this regard, the metal precursor typically has a decomposition temperature in the range from about 50° C. to about 500° C., in some embodiments from about 80° C. to about 400° C., and in some embodiments, from about 150° C. to about 300° C. In one embodiment, for example, the metal precursor may be an organic salt that contains a noble metal cation such as described above and an organic anion, such as a carboxylate, carbamate, formate, nitrate, etc., as well as combinations thereof. Particularly suitable carboxylates include linear carboxylates, such as acetate, propionate, butanoate, pentanoate, hexanoate, heptanoate, octanoate, nonanoate, decanoate, undecanoate, dodecanoate, tetradecanoate, hexadecanoate, octadecenoate, neopentanoate, neohexanoate, neoheptanoate, neooctanoate, neononanoate, neodecanoate and neododecanoate. Specific examples of such organic salts may include, for instance, silver acetate, silver propionate, silver butanoate, silver pentanoate, silver hexanoate, silver heptanoate, silver octanoate, silver nonanoate, silver decanoate, silver undecanoate, silver dodecanoate, silver tetradecanoate, silver hexadecanoate, silver octadecenoate, silver neopentanoate, silver neohexanoate, silver neoheptanoate, silver neooctanoate, silver neononanoate, silver neodecanoate, silver neododecanoate, and so forth, as well as combinations thereof.

The ink may also contain various other components besides metal particles and/or a metal precursor. For example, the ink may contain an organic solvent, such as hydrocarbons (e.g., terpenes, such as limonene, pinene, etc.), ethers (e.g., diethyl ether, tetrahydrofuran, propylene glycol ether, dipropylene glycol ether, etc.); alcohols (e.g., methanol, ethanol, n-propanol, iso-propanol, and butanol); triglycerides; ketones (e.g., acetone, methyl ethyl ketone, and methyl isobutyl ketone); esters (e.g., ethyl acetate, butyl acetate, diethylene glycol ether acetate, methoxypropyl acetate, ethylene carbonate, propylene carbonate, etc.); amides (e.g., dimethylformamide, dimethylacetamide, dimethylcaprylic/capric fatty acid amide and N-alkylpyrrolidones); lactones (e.g., γ-butyrolactone); nitriles (e.g., acetonitrile, propionitrile, butyronitrile and benzonitrile); sulfoxides or sulfones (e.g., dimethyl sulfoxide (DMSO) and sulfolane); and so forth. When employed, such solvent(s) typically constitute from about 10 wt. % to about 98 wt. %, in some embodiments from about 20 wt. % to about 96 wt. %, and in some embodiments, from about 50 wt. % to about 95 wt. % of the ink. The amount of the metal precursor(s) may likewise range from about 1 wt. % to about 60 wt. %, in some embodiments from about 5 wt. % to about 50 wt. %, and in embodiments, from about 10 wt. % to about 45 wt. % of the ink. Of course, the ink may also contain various other optional components, such as adhesion promoters (e.g., rhodium alkyl compounds, such as rhodium nonanoate), viscosity aids, silicones, preservatives (e.g., carboxylic acids), and additives.

The ink may be applied to a surface of the substrate to form one or more precursor layer(s) that cover the entire surface or in a pattern that covers only a portion of the surface. For example, the precursor layer(s) may cover from about 25% to about 95% of the surface, in some embodiments from about 30% to about 90% of the surface, and in some embodiments, from about 30% to about 85% of the surface. A variety of techniques may be used for applying the ink to the substrate. For instance, the ink may be printed onto the surface of the substrate, such as by rotogravure printing, gravure printing, screen printing, laser printing, thermal ribbon printing, piston printing, spray printing, flexographic printing, inkjet printing, etc. Inkjet printing may be particularly suitable as it is a non-contact printing technique that involves forcing the ink through a tiny nozzle (or a series of nozzles) to form droplets that are directed toward the substrate. Particularly suitable inkjet printing techniques are described, for instance, in WO 2020/094583 to Neumann, et al., which is incorporated herein by reference thereto. Of course, in addition to printing techniques, still other suitable application techniques may include bar, roll, knife, curtain, spray, slot-die, dip-coating, drop-coating, extrusion, stencil application, etc. A single layer or multiple layers may be printed on the surface of the substrate to achieve the desired film thickness.

As indicated above, the precursor layer(s) may be treated in a certain manner after application to form the conductive film. The treatment may include, for instance, direct heating (e.g., oven) and/or indirect heating, such as by subjecting the precursor layer(s) to electromagnetic radiation. For example, the precursor layer(s) may be heated at a temperature of from about 50° C. to about 500° C., in some embodiments from about 100° C. to about 350° C., and in some embodiments from about 150° C. to about 300° C. The total time of heating may vary depending on the temperature employed, but typically ranges from about 30 seconds to about 120 minutes, in some embodiments from about 1 minute to about 60 minutes, and in some embodiments, from about 5 minutes to about 30 minutes. When electromagnetic radiation is employed, some suitable examples may include, for instance, ultraviolet light, electron beam radiation, natural and artificial radio isotopes (e.g., α, β, and γ rays), x-rays, neutron beams, positively-charged beams, laser beams, infrared light, and so forth. When supplying electromagnetic radiation, it is generally desired to selectively control various parameters of the radiation to improve the quality of the resulting film. For example, one parameter that may be controlled is the wavelength of the electromagnetic radiation. The peak wavelength of the electromagnetic radiation may be about from about 100 nanometers to about 1 millimeter, in some embodiments from about 200 nanometers to about 100 micrometers, in some embodiments from about 500 nanometers to about 50 micrometers, in some embodiments from about 800 nanometers to about 10 micrometers, and in some embodiments, from about 1 micrometers to about 5 micrometers. The treatment may occur for a period of time of about 1 second to about 10 minutes, in some embodiments from about 2 seconds to about 2 minutes, and in some embodiments, from about 5 seconds to about 60 seconds. The total radiative flux density of the irradiation may also range of from about 0.1 to about 1000 kilowatts per square meter (kW/m²), in some embodiments from about 1 to about 500 kW/m², and in some embodiments, from about 10 to about 100 kW/m². It should be understood, however, that the actual dosage and/or flux density required depends on the type of materials employed in the ink and electromagnetic radiation.

The thickness of the resulting conductive film may vary, but is typically from about 5 nanometers to about 5 micrometers, in some embodiments from about 10 nanometers to about 2 micrometers, in some embodiments, from about 50 nanometers to about 1.8 micrometers, and in some embodiments, from about 200 nanometers to about 1.5 micrometers. The substrate thickness may likewise range from about 0.4 to about 10 millimeters, in some embodiments from about 0.5 to about 5 millimeters, and in some embodiments, from about 0.6 to about 4 millimeters.

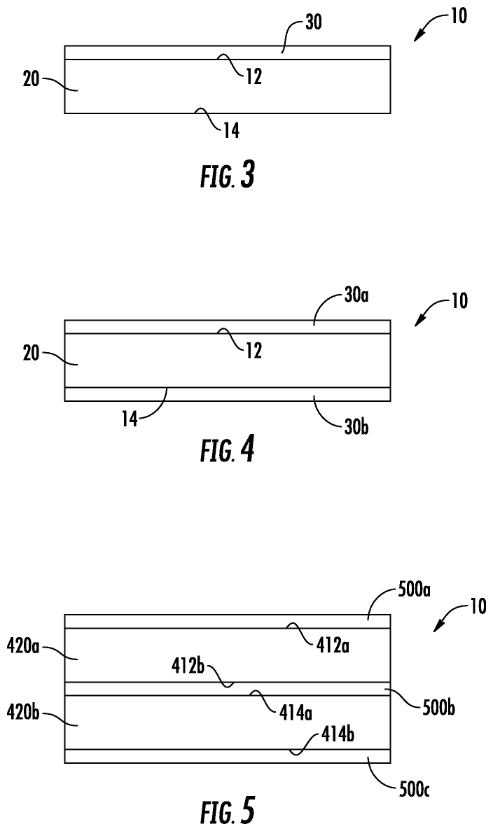

As indicated above, the conductive film is disposed on at least one surface of the substrate. Referring to FIG. 3, for example, one embodiment of a composite 10 is shown that contains a substrate 20 that defines a first surface 12 opposing a second surface 14. In this particular embodiment, a conductive film 30 is disposed on the first surface 12 of the substrate 20. Of course, conductive films may also be disposed on multiple surfaces of the substrate film. Referring to FIG. 4, for example, the composite 10 contains a conductive film 30a on the first surface 12 and a second conductive film 30b on the second surface 14. It should also be understood that the composite of the present invention may is by no means limited to the two- and three-layered embodiments referenced above. In certain cases, for example, the composite may contain multiple substrate and/or conductive films. For instance, as shown in FIG. 5, the composite may have a five-layer configuration that includes a first substrate 420a that defines a first surface 412a and an opposing second surface 412a and a second substrate 420b that defines a first surface 414a and an opposing second surface 414b. In this particular embodiment, a first conductive film 500a may be disposed on the first surface 412a of the first substrate 420a, a second conductive film 500b may be disposed on the second surface 412b of the first substrate 420a and the first surface 414a of the second substrate 420b, and a third conductive film 500c may be disposed on the second surface 414b of the second substrate 420b.

### II. Electronic Components

The composite of the present invention may be employed in a wide variety of electronic components to help impart EMI shielding. In one embodiment, for example, the composite may be employed in an electronic module. Such modules generally contain a housing that receives one or more electronic components (e.g., printed circuit board, antenna elements, radio frequency sensing elements, sensors, light sensing and/or transmitting elements (e.g., fibers optics), cameras, global positioning devices, etc.). The housing may, for instance, include a base that contains a sidewall extending therefrom. A cover may also be supported on the sidewall of the base to define an interior within which the electronic component(s) are received and protected from the exterior environment. Regardless of the particular configuration of the module, the composite may be used to form all or a portion of the housing and/or cover. In one embodiment, for instance, the composite may be used to form the base and sidewall of the housing. The cover may be formed from the composite of the present invention or from a different material. Notably, one benefit of the present invention is that conventional EMI metal shields (e.g., aluminum plates) and/or heat sinks can be eliminated from the module design, thereby reducing the weight and overall cost of the module. Nevertheless, in certain other embodiments, such additional shields and/or heat sinks may be employed. For example, the cover may contain an additional metal component (e.g., aluminum plate) in some cases.

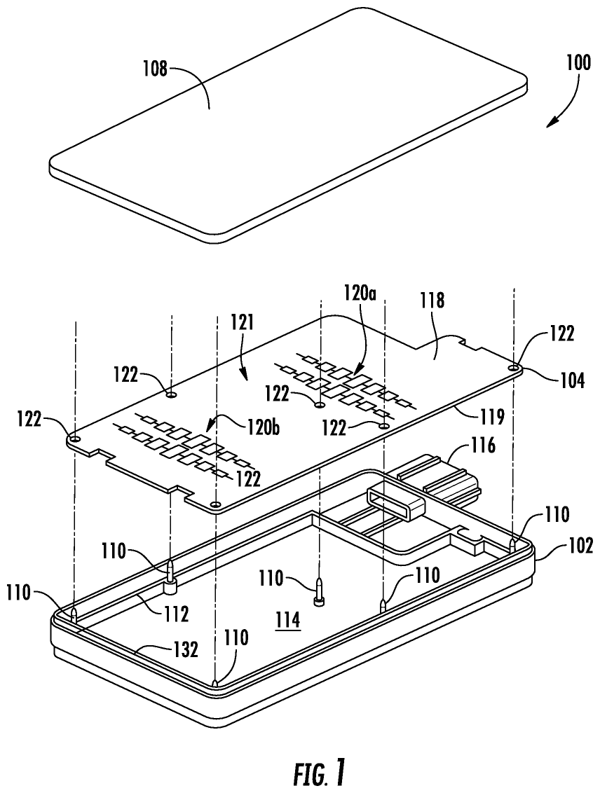

Referring to FIG. 1, for instance, one particular embodiment of an electronic module 100 is shown that may incorporate the composite of the present invention. The electronic module 100 includes a housing 102 that contains sidewalls 132 extending from a base 114. If desired, the housing 102 may also contain a shroud 116 that can accommodate an electrical connector (not shown). Regardless, a printed circuit board (“PCB”) is received within the interior of the module 100 and attached to housing 102. More particularly, the circuit board 104 contains holes 122 that are aligned with and receive posts 110 located on the housing 102. The circuit board 104 has a first surface 118 on which electrical circuitry 121 is provided to enable radio frequency operation of the module 100. For example, the RF circuitry 121 can include one or more antenna elements 120a and 120b. The circuit board 104 also has a second surface 119 that opposes the first surface 118 and may optionally contain other electrical components, such as components that enable the digital electronic operation of the module 100 (e.g., digital signal processors, semiconductor memories, input/output interface devices, etc.). Alternatively, such components may be provided on an additional printed circuit board. A cover 108 may also be employed that is disposed over the circuit board 104 and attached to the housing 102 (e.g., sidewall) through known techniques, such as by welding, adhesives, etc., to seal the electrical components within the interior. As indicated above, the composite of the present invention may be used to form all or a portion of the cover 108 and/or the housing 102. As noted above, because it possesses the unique combination of EMI shielding effectiveness and thermal conductivity, conventional EMI shields (e.g., aluminum plates) and/or heat sinks may be eliminated.

The electronic module may be used in a wide variety of applications. For example, the electronic module may be employed in an automotive vehicle (e.g., electric vehicle). When used in automotive applications, for instance, the electronic module may be used to sense the positioning of the vehicle relative to one or more three-dimensional objects. In this regard, the module may contain radio frequency sensing components, light detection or optical components, cameras, antenna elements, etc., as well as combinations thereof. For example, the module may be a radio detection and ranging (“radar”) module, light detection and ranging (“lidar”) module, camera module, global positioning module, etc., or it may be an integrated module that combines two or more of these components. Such modules may thus employ a housing that receives one or more types of electronic components (e.g., printed circuit board, antenna elements, radio frequency sensing devices, sensors, light sensing and/or transmitting elements (e.g., fibers optics), cameras, global positioning devices, etc.). In one embodiment, for example, a lidar module may be formed that contains a fiber optic assembly for receiving and transmitting light pulses that is received within the interior of a housing/cover assembly in a manner similar to the embodiments discussed above. Similarly, a radar module typically contains one or more printed circuit boards having electrical components dedicated to handling radio frequency (RF) radar signals, digital signal processing tasks, etc.

The electronic module may also be employed in a 5G system. For example, the electronic module may be an antenna module, such as macrocells (base stations), small cells, microcells or repeaters (femtocells), etc. As used herein, “5G” generally refers to high speed data communication over radio frequency signals. 5G networks and systems are capable of communicating data at much faster rates than previous generations of data communication standards (e.g., “4G, “LTE”). Various standards and specifications have been released quantifying the requirements of 5G communications. As one example, the International Telecommunications Union (ITU) released the International Mobile Telecommunications-2020 (“IMT-2020”) standard in 2015. The IMT-2020 standard specifies various data transmission criteria (e.g., downlink and uplink data rate, latency, etc.) for 5G. The IMT-2020 Standard defines uplink and downlink peak data rates as the minimum data rates for uploading and downloading data that a 5G system must support. The IMT-2020 standard sets the downlink peak data rate requirement as 20 Gbit/s and the uplink peak data rate as 10 Gbit/s. As another example, 3^{rd} Generation Partnership Project (3GPP) recently released new standards for 5G, referred to as “5G NR.” 3GPP published “Release 15” in 2018 defining “Phase 1” for standardization of 5G NR. 3GPP defines 5G frequency bands generally as “Frequency Range 1” (FR1) including sub-6 GHz frequencies and “Frequency Range 2” (FR2) as frequency bands ranging from 20-60 GHz. However, as used herein “5G frequencies” can refer to systems utilizing frequencies greater than 60 GHz, for example ranging up to 80 GHz, up to 150 GHz, and up to 300 GHz. As used herein, “5G frequencies” can refer to frequencies that are about 1.8 GHz or more, in some embodiments about 2.0 GHz or more, in some embodiments about 3.0 GHz or higher, in some embodiments from about 3 GHz to about 300 GHz, or higher, in some embodiments from about 4 GHz to about 80 GHz, in some embodiments from about 5 GHz to about 80 GHz, in some embodiments from about 20 GHz to about 80 GHz, and in some embodiments from about 28 GHz to about 60 GHz.

5G antenna systems generally employ high frequency antennas and antenna arrays for use in a 5G component, such as macrocells (base stations), small cells, microcells or repeaters (femtocell), etc., and/or other suitable components of 5G systems. The antenna elements/arrays and systems can satisfy or qualify as “5G” under standards released by 3GPP, such as Release 15 (2018), and/or the IMT-2020 Standard. To achieve such high speed data communication at high frequencies, antenna elements and arrays generally employ small feature sizes/spacing (e.g., fine pitch technology) that can improve antenna performance. For example, the feature size (spacing between antenna elements, width of antenna elements) etc. is generally dependent on the wavelength (“A”) of the desired transmission and/or reception radio frequency propagating through the substrate on which the antenna element is formed (e.g., nλ/4 where n is an integer). Further, beamforming and/or beam steering can be employed to facilitate receiving and transmitting across multiple frequency ranges or channels (e.g., multiple-in-multiple-out (MIMO), massive MIMO). The high frequency 5G antenna elements can have a variety of configurations. For example, the 5G antenna elements can be or include co-planar waveguide elements, patch arrays (e.g., mesh-grid patch arrays), other suitable 5G antenna configurations. The antenna elements can be configured to provide MIMO, massive MIMO functionality, beam steering, etc. As used herein “massive” MIMO functionality generally refers to providing a large number transmission and receiving channels with an antenna array, for example 8 transmission (Tx) and 8 receive (Rx) channels (abbreviated as 8×8). Massive MIMO functionality may be provided with 8×8, 12×12, 16×16, 32×32, 64×64, or greater.

The antenna elements may be fabricated using a variety of manufacturing techniques. As one example, the antenna elements and/or associated elements (e.g., ground elements, feed lines, etc.) can employ fine pitch technology. Fine pitch technology generally refers to small or fine spacing between their components or leads. For example, feature dimensions and/or spacing between antenna elements (or between an antenna element and a ground plane) can be about 1,500 micrometers or less, in some embodiments 1,250 micrometers or less, in some embodiments 750 micrometers or less (e.g., center-to-center spacing of 1.5 mm or less), 650 micrometers or less, in some embodiments 550 micrometers or less, in some embodiments 450 micrometers or less, in some embodiments 350 micrometers or less, in some embodiments 250 micrometers or less, in some embodiments 150 micrometers or less, in some embodiments 100 micrometers or less, and in some embodiments 50 micrometers or less. However, it should be understood that feature sizes and/or spacings that are smaller and/or larger may also be employed. As a result of such small feature dimensions, antenna configurations and/or arrays can be achieved with a large number of antenna elements in a small footprint. For example, an antenna array can have an average antenna element concentration of greater than 1,000 antenna elements per square centimeter, in some embodiments greater than 2,000 antenna elements per square centimeter, in some embodiments greater than 3,000 antenna elements per square centimeter, in some embodiments greater than 4,000 antenna elements per square centimeter, in some embodiments greater than 6,000 antenna elements per square centimeter, and in some embodiments greater than about 8,000 antenna elements per square centimeter. Such compact arrangement of antenna elements can provide a greater number of channels for MIMO functionality per unit area of the antenna area. For example, the number of channels can correspond with (e.g., be equal to or proportional with) the number of antenna elements.

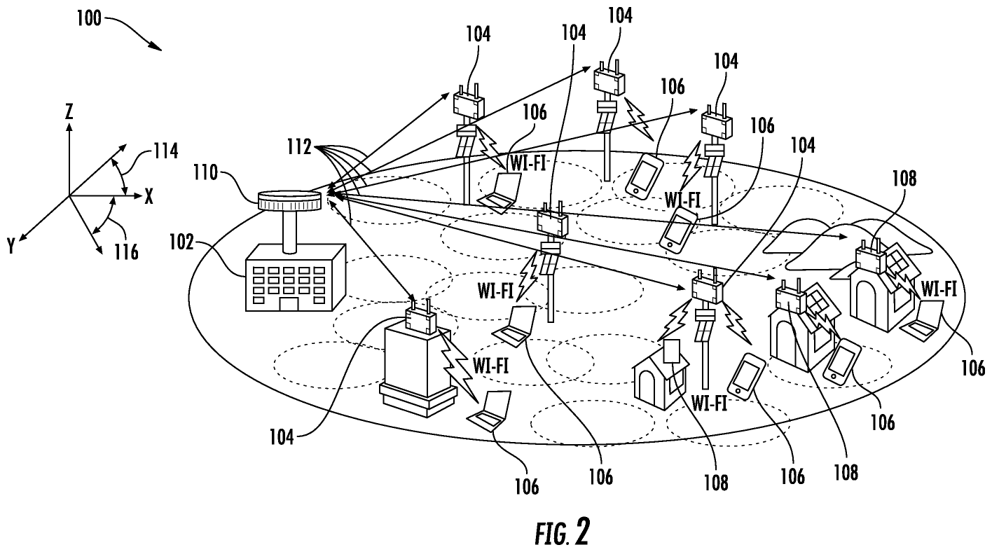

Referring to FIG. 2, for example, a 5G antenna system 100 can include a base station 102, one or more relay stations 104, one or more user computing devices 106, one or more Wi-Fi repeaters 108 (e.g., “femtocells”), and/or other suitable antenna components for the 5G antenna system 100. The relay stations 104 can be configured to facilitate communication with the base station 102 by the user computing devices 106 and/or other relay stations 104 by relaying or “repeating” signals between the base station 102 and the user computing devices 106 and/or relay stations 104. The base station 102 can include a MIMO antenna array 110 configured to receive and/or transmit radio frequency signals 112 with the relay station(s) 104, Wi-Fi repeaters 108, and/or directly with the user computing device(s) 106. The user computing device 306 is not necessarily limited by the present invention and include devices such as 5G smartphones. The MIMO antenna array 110 can employ beam steering to focus or direct radio frequency signals 112 with respect to the relay stations 104. For example, the MIMO antenna array 110 can be configured to adjust an elevation angle 114 with respect to an X-Y plane and/or a heading angle 116 defined in the Z-Y plane and with respect to the Z direction. Similarly, one or more of the relay stations 104, user computing devices 106, Wi-Fi repeaters 108 can employ beam steering to improve reception and/or transmission ability with respect to MIMO antenna array 110 by directionally tuning sensitivity and/or power transmission of the device 104, 106, 108 with respect to the MIMO antenna array 110 of the base station 102 (e.g., by adjusting one or both of a relative elevation angle and/or relative azimuth angle of the respective devices).

The present invention may be better understood by reference to the following examples.

### Test Methods

Thermal Conductivity: In-plane and through-plane thermal conductivity values are determined in accordance with ASTM E1461-13.

Electromagnetic Interference (“EMI”) Shielding: EMI shielding effectiveness may be determined in accordance with ASTM D4935-18 at frequency ranges ranging from 1.5 GHz to 10 GHz (e.g., 5 GHz). The thickness of the parts tested may vary, such as 1 millimeter, 1.6 millimeters, or 3 millimeters. The test may be performed using an EM-2108 standard test fixture, which is an enlarged section of coaxial transmission line and available from various manufacturers, such as Electro-Metrics. The measured data relates to the shielding effectiveness due to a plane wave (far field EM wave) from which near field values for magnetic and electric fields may be inferred.

Surface/Volume Resistivity: The surface and volume resistivity values are generally determined in accordance with IEC 62631-3-1:2016 or ASTM D257-14. According to this procedure, a standard specimen (e.g., 1 meter cube) is placed between two electrodes. A voltage is applied for sixty (60) seconds and the resistance is measured. The surface resistivity is the quotient of the potential gradient (in V/m) and the current per unit of electrode length (in A/m), and generally represents the resistance to leakage current along the surface of an insulating material. Because the four (4) ends of the electrodes define a square, the lengths in the quotient cancel and surface resistivities are reported in ohms, although it is also common to see the more descriptive unit of ohms per square. Volume resistivity is also determined as the ratio of the potential gradient parallel to the current in a material to the current density. In SI units, volume resistivity is numerically equal to the direct-current resistance between opposite faces of a one-meter cube of the material (ohm-m).

Melt Viscosity: The melt viscosity (Pa-s) may be determined in accordance with ISO Test No. 11443:2021 at a shear rate of 1,000 s⁻¹ and temperature 15° C. above the melting temperature using a Dynisco LCR7001 capillary rheometer. The rheometer orifice (die) had a diameter of 1 mm, length of 20 mm, L/D ratio of 20.1, and an entrance angle of 180°. The diameter of the barrel was 9.55 mm+0.005 mm and the length of the rod was 233.4 mm.

Melting Temperature: The melting temperature (“Tm”) may be determined by differential scanning calorimetry (“DSC”) as is known in the art. The melting temperature is the differential scanning calorimetry (DSC) peak melt temperature as determined by ISO Test No. 11357-2:2020. Under the DSC procedure, samples were heated and cooled at 20° C. per minute as stated in ISO Standard 10350 using DSC measurements conducted on a TA Q2000 Instrument.

Deflection Temperature Under Load (“DTUL”): The deflection under load temperature may be determined in accordance with ISO Test No. 75-2:2013 (technically equivalent to ASTM D648). More particularly, a test strip sample having a length of 80 mm, thickness of 10 mm, and width of 4 mm may be subjected to an edgewise three-point bending test in which the specified load (maximum outer fibers stress) was 1.8 Megapascals. The specimen may be lowered into a silicone oil bath where the temperature is raised at 2° C. per minute until it deflects 0.25 mm (0.32 mm for ISO Test No. 75-2:2013).

Tensile Modulus, Tensile Stress, and Tensile Elongation: Tensile properties may be tested according to ISO Test No. 527:2019 (technically equivalent to ASTM D638). Modulus and strength measurements may be made on the same test strip sample having a length of 80 mm, thickness of 10 mm, and width of 4 mm. The testing temperature may be 23° C., and the testing speeds may be 1 or 5 mm/min.

Flexural Modulus, Flexural Stress, and Flexural Elongation: Flexural properties may be tested according to ISO Test No. 178:2019 (technically equivalent to ASTM D790). This test may be performed on a 64 mm support span. Tests may be run on the center portions of uncut ISO 3167 multi-purpose bars. The testing temperature may be 23° C. and the testing speed may be 2 mm/min.

Unnotched and Notched Charpy Impact Strength: Charpy properties may be tested according to ISO Test No. ISO 179-1:2010) (technically equivalent to ASTM D256-10, Method B). This test may be run using a Type 1 specimen size (length of 80 mm, width of 10 mm, and thickness of 4 mm). When testing the notched impact strength, the notch may be a Type A notch (0.25 mm base radius). Specimens may be cut from the center of a multi-purpose bar using a single tooth milling machine. The testing temperature may be 23° C.

Metal Content: An inductively coupled plasma (ICP) is coupled with optical emission spectrometry (OES) for evaluation. Typical determination limits according to the method used here are “ppm” (related to the weighed sample quantity). The determination of the element concentration with the measuring instrument is carried out according to the specifications of the instrument manufacturer (ICP-OES: VARIAN Vista MPX) and using certified reference liquids for calibration. The element concentration in the solution (100 ml) determined by the instruments is then converted to the original sample weight (0.1 g).

Specific Conductance and Conductive Efficiency: The specific conductance of the layer (S/m) may be measured at a temperature of 20° C. using a four-point probe of Ossila (based on the median film thickness as determined with the profilometer Dektak DXT-E). The conductive efficiency may likewise be calculated by dividing the specific conductance of the layer by the bulk value of the primary metal used to form the layer, and then multiplying the resulting quotient by 100. Silver, for example, has a bulk value of 6.3×10⁷ S/m at a temperature of 20° C.

### Example 1

A composite is formed from a substrate that includes a commercially available polymer composition that contains approximately 55 wt. % of a liquid crystalline polymer, 29 wt. % talc, and 15 wt. % glass fibers, and 1 wt. % of various additives. The substrate has a size of 15×15 cm. The substrate is pre-treated with air-plasma and then five (5) layers of an ink containing silver were ink-jet printed onto one surface of the substrate and heated in an oven at 210° C. for 15 minutes. The resulting film had a thickness of about 1 micrometer.

### Example 2

A composite is formed from a substrate that includes a commercially available polymer composition that contains approximately 35-50 wt. % of polyphenylene sulfide (PPS), 40-55 wt. % graphite, and 10 wt. % glass fibers. The substrate has a size of 15×15 cm. The substrate is pre-treated with air-plasma and then five (5) layers of an ink containing silver were ink-jet printed onto one surface of the substrate and heated in an oven at 215° C. for 15 minutes. The resulting film had a thickness of about 1 micrometer.

### Example 3

A composite is formed from a commercially available polymer composition that contains approximately 55 wt. % polybutylene terephthalate, 25 wt. % flake graphite, 10 wt. % glass fibers, and 10 wt. % of various additives. The substrate has a size of 15×15 cm. The substrate is pre-treated with air-plasma and then five (5) layers of an ink containing silver were ink-jet printed onto one surface of the substrate and heated in an oven at 215° C. for 10 minutes. The resulting film had a thickness of about 1 micrometer.

### Example 4

A composite is formed from a substrate that includes a commercially available polymer composition that contains approximately 76 wt. % nylon 6,6, 20 wt. % carbon fibers, and 4 wt. % of additives. The substrate has a size of 15×15 cm. The substrate is pre-treated with a powder and then five (5) layers of an ink containing silver were ink-jet printed onto one surface of the substrate and heated in an oven at 210° C. for 15 minutes. The resulting film had a thickness of about 1 micrometer.

Ten (10) samples of the composites of Examples 1-4 were tested for the average EMI shielding effectiveness (SE) before and after being coated with the conductive film. The results are set forth below in Table 1.

TABLE 1
Average EMI Shielding Effectiveness (SE) (dB)

| | | Example 1 | Example 1 | Example 2 | Example 2 | Example 3 | Example 3 | Example 4 | Example 4 |
|---|---|---|---|---|---|---|---|---|---|
| | | (prior to | (after | (prior to | (after | (prior to | (after | (prior to | (after |
| Frequency | | coating) | coating) | coating) | coating) | coating) | coating) | coating) | coating) |
| 2 | GHz | 1.23 | 52.32 | 41.28 | 56.84 | 38.26 | 58.85 | 21.87 | 61.34 |
| 4 | GHz | 1.53 | 61.29 | 53.65 | 63.86 | 52.34 | 57.76 | 32.03 | 61.34 |
| 6 | GHz | 3.20 | 57.56 | 61.15 | 63.70 | 60.75 | 61.38 | 36.95 | 62.63 |
| 8 | GHz | 1.99 | 56.21 | 71.30 | 67.29 | 58.57 | 65.82 | 40.25 | 66.48 |
| 10 | GHz | 0.48 | 55.27 | 54.95 | 56.26 | 52.09 | 56.09 | 45.78 | 56.91 |
| 12 | GHz | 0.98 | 52.11 | 51.05 | 54.01 | 54.20 | 55.01 | 46.91 | 52.74 |
| 14 | GHz | 0.81 | 53.43 | 51.62 | 54.91 | 52.98 | 52.38 | 47.62 | 53.25 |
| 16 | GHz | 0.41 | 50.64 | 54.72 | 52.17 | 51.54 | 50.23 | 46.11 | 49.99 |

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. A multi-layered composite comprising:
a substrate defining a first surface and an opposing second surface, wherein the substrate contains a polymer composition that includes a polymer matrix, wherein the polymer matrix contains a thermoplastic polymer having a deflection temperature under load of about 40° C. or more as determined in accordance with ISO 75-2:2013 at a load of 1.8 MPa; and
a conductive film disposed on the first surface, wherein the film contains a noble metal;
wherein the composite exhibits an electromagnetic interference shielding effectiveness of about 25 decibels or more as determined in accordance with ASTM D4935-18 at a frequency of 10 GHz and thickness of 3 millimeters.

2. The multi-layered composite of claim 1, wherein the composite exhibits an average electromagnetic interference shielding effectiveness of about 25 decibels or more over a frequency range of from about 0.4 GHz to about 18 GHz and at a thickness of 3 millimeters.

3. The multi-layered composite of claim 1, wherein the composite exhibits an electromagnetic interference shielding effectiveness of about 50 decibels or more at a frequency of 10 GHz and at a thickness of 3 millimeters.

4. The multi-layered composite of claim 1, wherein the polymer matrix constitutes from about 50 wt. % to 100 wt. % of the composition.

5. The multi-layered composite of claim 1, wherein the thermoplastic polymer has a glass transition temperature of about 10° C. or more.

6. The multi-layered composite of claim 1, wherein the thermoplastic polymer has a melting temperature of about 140° C. or more.

7. The multi-layered composite of claim 1, wherein the thermoplastic polymer includes an aromatic polymer.

8. The multi-layered composite of claim 7, wherein the aromatic polymer is an aromatic polyester.

9. The multi-layered composite of claim 8, wherein the aromatic polyester is poly(ethylene terephthalate), poly(1,4-butylene terephthalate), poly(1,3-propylene terephthalate), poly(1,4-butylene 2,6-naphthalate), poly(ethylene 2,6-naphthalate), poly(1,4-cyclohexylene dimethylene terephthalate), or a combination thereof.

10. The multi-layered composite of claim 7, wherein the aromatic polymer is a polyarylene sulfide.

11. The multi-layered composite of claim 7, wherein the aromatic polymer is an aromatic polycarbonate.

12. The multi-layered composite of claim 7, wherein the aromatic polymer is a thermotropic liquid crystalline polymer.

13. The multi-layered composite of claim 7, wherein the aromatic polymer is an aromatic polyamide.

14. The multi-layered composite of claim 1, wherein the thermoplastic polymer includes an aliphatic polymer.

15. The multi-layered composite of claim 14, wherein the aliphatic polymer is an aliphatic polyamide.

16. The multi-layered composite of claim 14, wherein the aliphatic polymer is a propylene polymer.

17. The multi-layered composite of claim 1, wherein the polymer composition further comprises a mineral filler.

18. The multi-layered composite of claim 1, wherein the polymer composition further comprises reinforcing fibers.

19. The multi-layered composite of claim 1, wherein polymer composition exhibits an in-plane thermal conductivity of about 1 W/m-K or more as determined in accordance with ASTM E 1461-13.

20. The multi-layered composite of claim 1, wherein the polymer composition exhibits a surface resistivity of about 1×10¹⁴ ohms or more and/or a volume resistivity of about 1×10¹² ohm-m or more, as determined at a temperature of about 20° C. in accordance with IEC 62631-3-1:2016.

21. The multi-layered composite of claim 1, wherein the polymer composition is free of an electrically conductive filler.

22. The multi-layered composite of claim 1, wherein the polymer composition contains copper in an amount of about 1,000 parts per million or less and chromium in an amount of about 2,000 parts per million or less,

23. The multi-layered composite of claim 1, wherein the polymer composition is free of spinel crystals having the formula, AB₂O₄, wherein A is a metal cation having a valance of 2 and B is a metal cation having a valance of 3.

24. The multi-layered composite of claim 1, wherein the polymer composition is free of copper chromite.

25. The multi-layered composite of claim 1, wherein the noble metal includes ruthenium, rhodium, palladium, osmium, platinum, gold, silver, copper, or a combination thereof.

26. The multi-layered composite of claim 1, wherein the noble metal includes silver.

27. The multi-layered composite of claim 1, wherein the conductive film is free of metal particles having an average of diameter of about 1 micrometer or more.

28. The multi-layered composite of claim 1, wherein the conductive film exhibits a specific conductance of about 1×10⁵ S/cm or more at a temperature of 20° C.

29. The multi-layered composite of claim 1, wherein the conductive film has a thickness of from about 5 nanometers to about 5 micrometers.

30. The multi-layered composite of claim 1, further comprising a second conductive film disposed on the second surface, wherein the second conductive film contains a noble metal.

31. A method for forming the composite of claim 1, the method comprising:
applying an ink to the first surface to form one or more precursor layers, wherein the ink comprises a noble metal or noble metal precursor; and
treating the one or more precursor layers to form the conductive film.

32. The method of claim 31, wherein the ink comprises metal particles.

33. The method of claim 31, wherein the ink comprises a metal precursor.

34. The method of claim 33, wherein the metal precursor has a decomposition temperature of from about 50° C. to about 500° C.

35. The method of claim 33, wherein the metal precursor is an organic salt that contains a noble metal cation and an organic anion.

36. The method of claim 35, wherein the metal precursor includes silver butanoate, silver pentanoate, silver hexanoate, silver heptanoate, silver octanoate, silver nonanoate, silver decanoate, silver undecanoate, silver dodecanoate, silver tetradecanoate, silver hexadecanoate, silver octadecenoate, silver neopentanoate, silver neohexanoate, silver neoheptanoate, silver neooctanoate, silver neononanoate, silver neodecanoate, silver neododecanoate, or a combination thereof.

37. The method of claim 31, wherein the treating includes heating the one or more precursor layers.

38. The method of claim 31, wherein the treating includes subjecting the one or more precursor layers to electromagnetic radiation.

39. The method of claim 38, wherein the electromagnetic radiation has a peak wavelength of from about 100 nanometers to about 1 millimeter.

40. The method of claim 31, wherein the ink is printed onto the first surface of the substrate.

41. The method of claim 31, further comprising applying the ink to the second surface to form one or more second precursor layers and treating the one or more second precursor layers to form the second conductive film.
